(19) United States
(12) Patent Application Publication
(10) Pub. No.: US 2012/0056253 A1
(43) Pub. Date: Mar. 8, 2012

(54) SEMICONDUCTOR MEMORY DEVICE AND MANUFACTURING METHOD THEREOF

(75) Inventors: Masayoshi IWAYAMA, Yokohama-shi (JP); Hiroyuki Kanaya, Yokohama-shi (JP)

(73) Assignee: KABUSHIKI KAISHA TOSHIBA, Tokyo (JP)

(21) Appl. No.: 12/943,404

(22) Filed: Nov. 10, 2010

(30) Foreign Application Priority Data
Sep. 7, 2010 (JP) 2010-199658

(51) Int. Cl. H01L 29/78; H01L 21/336

(52) U.S. Cl. 257/295; 438/3; 257/E29.272; 257/E21.436

(57) ABSTRACT

A semiconductor memory device according to the present embodiment includes a semiconductor substrate, a select transistor, a lower electrode, a magnetic tunnel junction element, a first protection film, an upper electrode, and a second protection film. The select transistor is formed on the semiconductor substrate. The lower electrode is electrically connected to one diffusion layer of the select transistor. The magnetic tunnel junction element is provided on the lower electrode. The first protection film is provided on a side surface of the magnetic tunnel junction element. The upper electrode is provided on the magnetic tunnel junction element and the first protection film. The second protection film is provided on side surfaces of the upper electrode, the first protection film, and the lower electrode.

### CROSS REFERENCE TO RELATED APPLICATIONS

This application is based upon and claims the benefit of priority from the prior Japanese Patent Application No. 2010-199658, filed on Sep. 7, 2010, the entire contents of which are incorporated herein by reference.

### FIELD

The embodiments of the present invention relate to a semiconductor memory device and manufacturing method thereof.

### BACKGROUND

An MRAM (Magnetic Random Access Memory) has been developed as a resistive variable element that uses resistance change of an element to store data. A writing method of the MRAM includes a magnetic-field writing method and a spin-injection writing method. In the magnetic field writing method, if the size of an MTJ (Magnetic Tunnel Junction) element is reduced, a writing current tends to increase because a coercivity increases. On the other hand, in the spin injection writing method, a spin injection current required for a magnetization inversion decreases with a decrease of the size of a magnetic body because it employs an STT (Spin Transfer Torque) writing method. Therefore, an MTJ element of the spin injection writing method has an advantage in a high degree of integration, low power consumption, and high performance. In addition, although there is a possibility that an erroneous writing occurs in a non-selected memory cell due to spreading of a magnetic field in the magnetic field writing method, such an erroneous writing in a non-selected memory cell does not occur in the spin injection writing method.

In order to downscale the MRAM, it is required to adopt the spin injection writing method and to carry on further downscaling of the MTJ element. However, a downscaled MTJ element is susceptible to hydrogen radical (H radical), H₂O, O₂ and the like generated in a BEOL (Back End Of Line) process such as a wiring forming process, and is easily degraded.

### BRIEF DESCRIPTION OF THE DRAWINGS

FIG. 1 is a cross-sectional diagram showing a configuration of a memory cell MC of an MRAM according to an embodiment of the present invention;

FIG. 2 is a cross-sectional diagram showing the MTJ element and its peripheral structure according to the present embodiment; and

FIG. 3 to FIG. 6 are cross-sectional diagrams showing a method of manufacturing an MRAM according to the present embodiment.

### DETAILED DESCRIPTION

A semiconductor memory device according to the present embodiment includes a semiconductor substrate, a select transistor, a lower electrode, a magnetic tunnel junction element, a first protection film, an upper electrode, and a second protection film. The select transistor is formed on the semiconductor substrate. The lower electrode is electrically connected to one diffusion layer of the select transistor. The magnetic tunnel junction element is provided on the lower electrode. The first protection film is provided on a side surface of the magnetic tunnel junction element. The upper electrode is provided on the magnetic tunnel junction element and the first protection film. The second protection film is provided on side surfaces of the upper electrode, the first protection film, and the lower electrode.

Embodiments will now be explained with reference to the accompanying drawings. These embodiments do not limit the present invention.

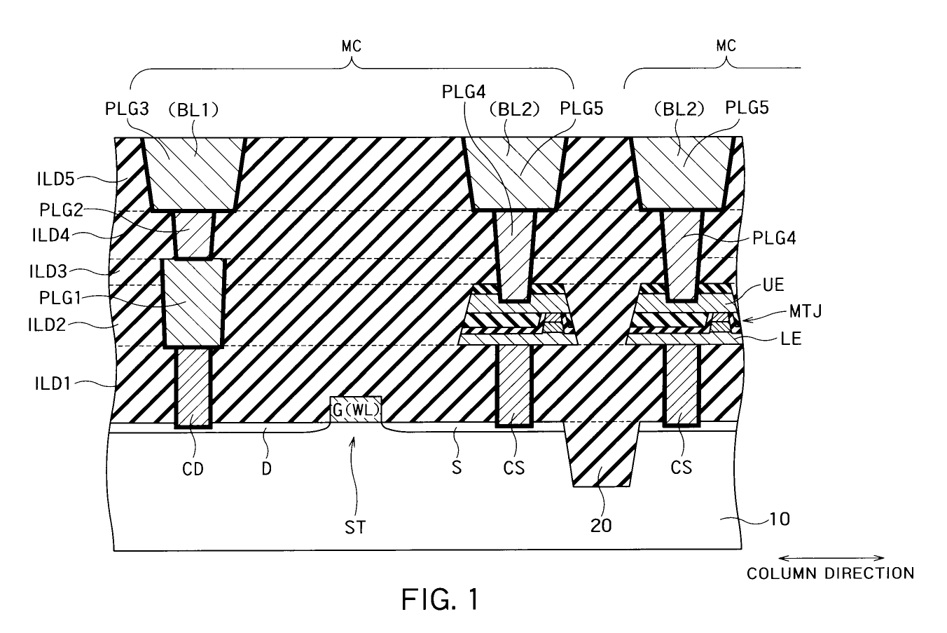

FIG. 1 is a cross-sectional diagram showing a configuration of a memory cell MC of an MRAM according to an embodiment of the present invention. The memory cell MC is configured by an MTJ element and a select transistor ST. The MTJ element and the select transistor ST are connected in series between a pair of bit lines BL1 and BL2.

The select transistor ST includes a gate electrode G (a word line WL) and an impurity diffusion layer (a source S and a drain D). The gate electrode G extends in a row direction (a vertical direction with respect to the plane of FIG. 1), and has a function of a word line WL as well as a function of a gate electrode. The drain D is electrically connected to the bit line BL1 via a drain contact CD and contact plugs PLG1 to PLG3. The source S is electrically connected to a lower electrode LE, which is provided below the MTJ element, via a source contact CS.

The MTJ element is connected between the lower electrode LE and an upper electrode UE. The upper electrode UE is connected to the bit line BL2 via contact plugs PLG4 and PLG5.

Both the bit lines BL1 and BL2 extend in a column direction, while being insulated from each other. Therefore, although it is omitted from in FIG. 1, the bit lines BL1 and BL2 are arranged being shifted from each other in the row direction. With this arrangement, it is possible to apply a voltage difference between the bit lines BL1 and BL2.

An STI (Shallow Trench Isolation) 20 is provided between two adjacent memory cells MC for separating the memory cells MC. The MTJ element, the drain contact CD, the source contact CS, and the contact plugs PLG1 to PLG5 are surrounded by interlayer dielectric films ILD1 to ILD5. The material of each of the interlayer dielectric films ILD1 to ILD5 is not particularly limited as long as it is an insulating material having a low dielectric constant. The material of each of the interlayer dielectric films ILD1 to ILD5 can be silicon nitride or silicon oxide, for example.

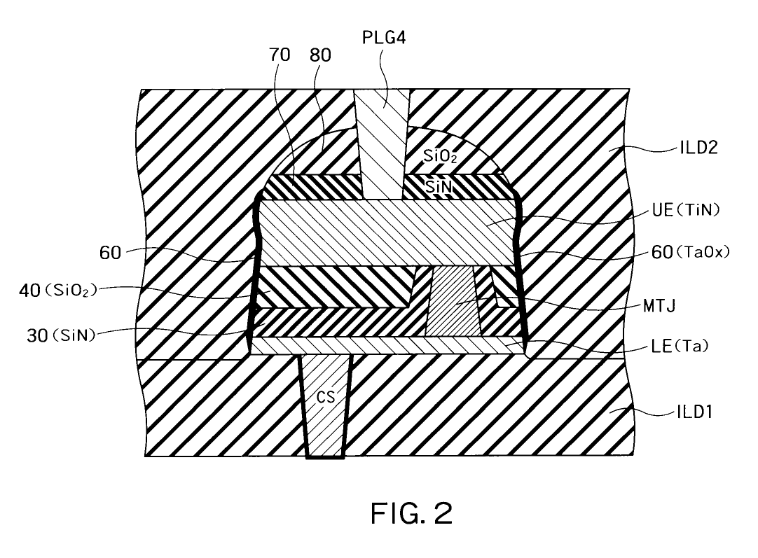

FIG. 2 is a cross-sectional diagram showing the MTJ element and its peripheral structure according to the present embodiment. In FIG. 2, a structure above the interlayer dielectric film ILD1 is shown while omitting the select transistor ST from the drawing.

The lower electrode LE is formed on the source contact CS and the interlayer dielectric film ILD1. Accordingly, the lower electrode LE is electrically connected to the source S via the source contact CS. The material of the lower electrode LE is a conductive material, such as Ta, Al, Ir, Ti, W, or Zr. The material of the lower electrode LE is used later for forming a second protection film 60 covering side surfaces of the upper electrode UE, a first protection film 30, and an insulation film 40. Therefore, the material of the lower electrode LE becomes an insulating material by being oxidized. Furthermore, it is preferable that the material of the lower electrode LE is a material that is easy to be remained as a residue at the time of etching. That is, it is preferable that the material of the lower electrode LE is a material having conductivity before being oxidized and having an insulation characteristic after being oxidized, and being easy to be remained as an etching residue. The first protection film 30 can be a laminated film. For example, the first protection film 30 can be a laminated film of a first insulation film provided directly on a side surface of the MTJ element and a second insulation film (not shown) provided on the side surface of the MTJ element via the first insulation film.

The MTJ element is provided on the lower electrode LE. The MTJ element has a layered structure of a fixed layer, a tunnel barrier film, and a recording layer in order. The material of the fixed layer is a magnetic layer containing Co, Fe, Ni, Pt, Fe, Pd, B, Ta, Dy, Tv, or Cr, for example. The material of the tunnel barrier film is magnesium oxide, for example. The material of the recording layer is a magnetic layer containing Co, Fe, Ni, Pt, Fe, Pd, B, Ta, Dy, Tv, or Cr, for example. A magnetization direction of the fixed layer is fixed. Therefore, the MTJ element stores data therein according to a magnetization direction of the recording layer. The MTJ element can take a low resistive state and a high resistive state according to a magnetization arrangement of two ferromagnetic layers. For example, if the low resistive state is defined as data “0” and the high resistive state is defined as data “1”, the MTJ element can record 1-bit data.

The first protection film 30 directly contacts with the side surface of the MTJ element. The insulation film 40 is provided on the side surface of the MTJ element via the first protection film 30. The material of the first protection film 30 is silicon nitride, for example, and the material of the insulation film 40 is silicon oxide deposited by HDP (High Density Plasma), for example. The first protection film 30 protects the side surface of the MTJ element.

The upper electrode UE is provided on the first protection film 30, the insulation film 40, and the MTJ element. The material of the upper electrode UE is a conductive material, and can be any of a material such as Ta, TiAlxNy, TaN, WN, W, or TiN.

Side surfaces of the upper electrode UE, the first protection film 30, the insulation film 40, and the lower electrode LE are covered by the second protection film 60. The material of the second protection film 60 is made of metal oxide having an insulation characteristic. The material of the second protection film 60 is made of TaOx, AlOx, IrOx, or ZrOx, for example, where x is a positive value. It is preferable that the second protection film 60 is a metal oxide film obtained by oxidizing the material of the lower electrode LE. With this arrangement, the second protection film 60 is obtained by oxidizing the metal attached on the side surfaces of the upper electrode UE, the first protection film 30, and the insulation film 40 at the time of etching the lower electrode LE. That is, a process of forming the second protection film 60 can be simplified.

Because the second protection film 60 is configured by an insulating material, the upper electrode UE and the lower electrode LE are not electrically connected to each other. Therefore, even though the second protection film 60 is provided, it is possible to maintain an electrically insulating state between the upper electrode UE and the lower electrode LE.

For example, the metal oxide such as TaOx, AlOx, IrOx, or ZrOx is hard to pass H radical, H₂O, and O₂. Therefore, the second protection film 60 can prevent a degradation factor such as H radical, H₂O, and O₂ from penetrating through a boundary between the first protection film 30 or the insulation film 40 and the upper electrode UE or a boundary between the MTJ element and the upper electrode UE. The H radical tends to be produced at the time of sinter annealing, at which the MTJ element is easily degraded.

If the thickness of a metal residue attached on the side surfaces of the upper electrode UE, the first protection film 30, and the insulation film 40 is too large, it is not possible to oxidize the whole metal residue film in the oxidizing process. In this case, the upper electrode UE and the lower electrode LE are short-circuited by the second protection film 60. In order to avoid this kind of problem, it is preferable that the thickness of the metal residue attached on the side surfaces of the upper electrode UE, the first protection film 30, and the insulation film 40 is about several nm to 30 nm. With the thickness of the metal residue equal to or larger than several nm, the second protection film 60 can prevent penetration of the degradation factor such as H radical, H₂O, and O₂. With the thickness of the metal residue equal to or less than 30 nm, the metal residue can be completely oxidized and makes it possible to prevent the upper electrode UE and the upper electrode UE from being short-circuited.

A silicon nitride film 70 and a silicon oxide film 80 that are used as a hard mask are provided on the upper electrode UE. The interlayer dielectric film ILD2 is provided to cover the second protection film 60, the silicon nitride film 70, and the silicon oxide film 80. The contact plug PLG4 penetrates the interlayer dielectric film ILD2, the silicon nitride film 70, and the silicon oxide film 80 and is electrically connected to the upper electrode UE.

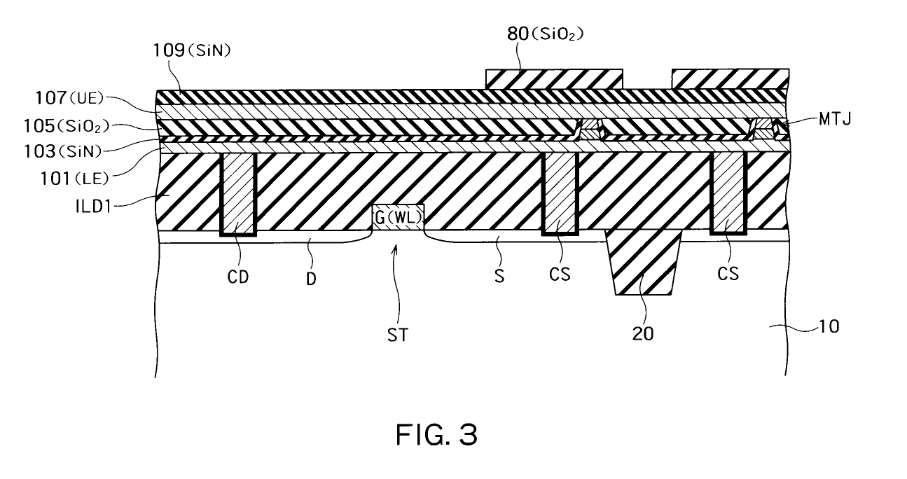

FIG. 3 to FIG. 6 are cross-sectional diagrams showing a method of manufacturing an MRAM according to the present embodiment. Firstly, a semiconductor substrate 10 such as a silicon substrate is prepared. The STI 20 is formed on the semiconductor substrate 10, and the select transistor ST is formed in an active area. The interlayer dielectric film ILD1 is deposited to cover the select transistor ST, and a surface of the interlayer dielectric film ILD1 is flattened. Thereafter, the source contact CS and the drain contact CD respectively reaching the source S and the drain D of the select transistor ST are formed in the interlayer dielectric film ILD1.

Subsequently, a lower electrode material 101 is deposited on the interlayer dielectric film ILD1, the source contact CS, and the drain contact CD. The MTJ element is formed on the lower electrode material 101. A method of forming the MTJ element is as follows. Firstly, the material of the fixed layer, the material of the tunnel barrier film, and the material of the recording layer are deposited in this order. These materials are as described above.

Thereafter, the material of a hard mask (not shown) is deposited on the material of the MTJ element. The material of the hard mask is SiO₂ or SiN, for example. The material of the hard mask is processed in a plane pattern of the MTJ element. The MTJ element is then processed by RIE (Reactive Ion Etching) using the hard mask as a mask. With this operation, the MTJ element is formed. The MTJ element is arranged at a position deviated from a line of the source contact CS and the contact plug PLG4. This arrangement is to suppress a characteristic degradation of the MTJ element due to a roughness and a crystal structure on the contact plug.

Subsequently, a silicon nitride film 103 and a silicon oxide film 105 are deposited as the material of the first protection film 30 to cover a top surface and the side surface of the MTJ element. The silicon oxide film 105 and the silicon nitride film 103 are then polished until the top surface of the MTJ element is exposed by using CMP (Chemical Mechanical Polishing). At this time, the silicon oxide film 105 and the silicon nitride film 103 are still in a state of covering the side surface of the MTJ element.

Thereafter, an upper electrode material 107 and an insulation film 109 are sequentially deposited on the silicon oxide film 105, the silicon nitride film 103, and the MTJ element.

Subsequently, a silicon oxide film is deposited as the hard mask 80, and the silicon oxide film is processed by using a lithography and the RIE. At this time, the silicon oxide film is formed in a plane pattern of a structure including the MTJ element. With this operation, a structure shown in FIG. 3 is obtained.

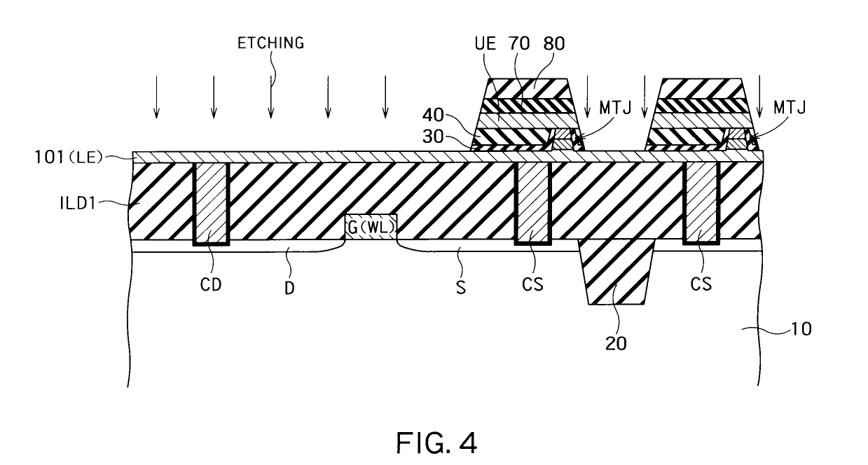

Thereafter, the insulation film 109, the upper electrode material 107, the silicon oxide film 105, and the silicon nitride film 103 are etched by the RIE using the hard mask 80 as a mask. With this operation, the upper electrode UE, the first protection film 30, and the insulation film 40 are formed as shown in FIG. 4. At this time, the lower electrode material 101 is still remained without being etched. The lower electrode material 101 can function as an etching stopper at the time of etching the above materials.

Subsequently, the lower electrode material 101 is etched by using the hard masks 80 and 70, the upper electrode UE, the first protection film 30, and the insulation film 40 as a mask. The lower electrode material 101 is processed by using the RIE, IBE (Ion Beam Etching) and the like. As for an etching condition at this time, it is preferable to be a condition with a high bias in which a fence is easily formed on the side surface. For example, the lower electrode material 101 is etched with a bias of 200 watts in an atmosphere in which oxygen (O₂) and chlorine (Cl) are supplied with a flow rate of 180 sccm and 20 sccm, respectively. At this time, the lower electrode material 101 is rebounded and attached on each side surface of the upper electrode UE, n the side surfaces of the first protection film 30, and n the side surfaces of the insulation film 40 by a physical operation. A thickness of the lower electrode material 101 attached on the side surfaces of the upper electrode UE, on the side surfaces of the first protection film 30, and on the side surfaces of the insulation film 40 can be controlled by an etching time. In this manner, the material of the second protection film 60 is attached as a residue on the side surfaces of the upper electrode UE, on the side surfaces of the first protection film 30, and on the side surfaces of the insulation film 40 simultaneously with formation of the lower electrode LE.

It is possible to perform the etching of the lower electrode material 101 and oxidization of the lower electrode material 101 attached on the side surfaces of the upper electrode UE, on the side surfaces of the first protection film 30, and on the side surfaces of the insulation film 40 simultaneously (in the same process) by performing the etching of the lower electrode material 101 in the oxidizing atmosphere. In this case, the second protection film 60 is formed on the side surfaces of the upper electrode UE, the first protection film 30, and the insulation film 40 simultaneously with the formation of the lower electrode LE.

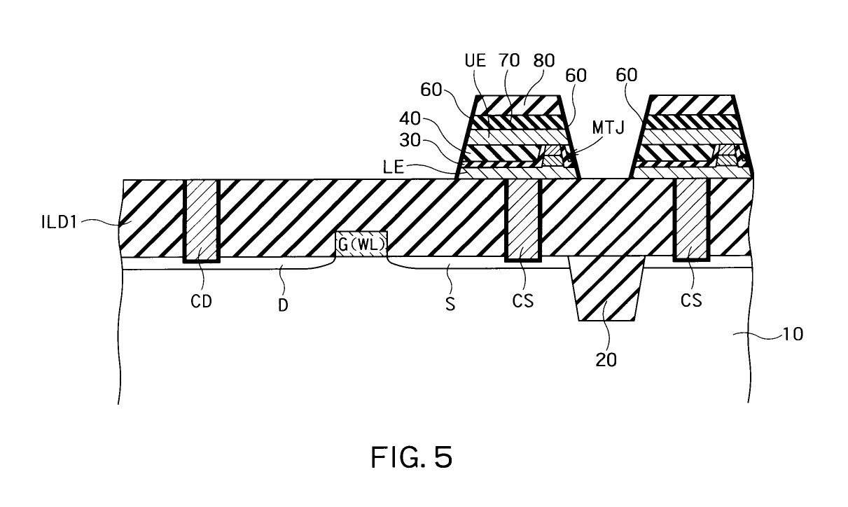

When the etching of the lower electrode material 101 is not performed in the oxidizing atmosphere or when the oxidization of the lower electrode material 101 attached on the side surfaces of the upper electrode UE, the first protection film 30, and the insulation film 40 is insufficient, a thermal process is performed after forming the lower electrode LE, to oxidize the material of the second protection film 60 attached on the side surfaces of the upper electrode UE, the first protection film 30, and the insulation film 40. At this time, the second protection film 60 becomes an insulation film. With this operation, a structure shown in FIG. 5 is obtained.

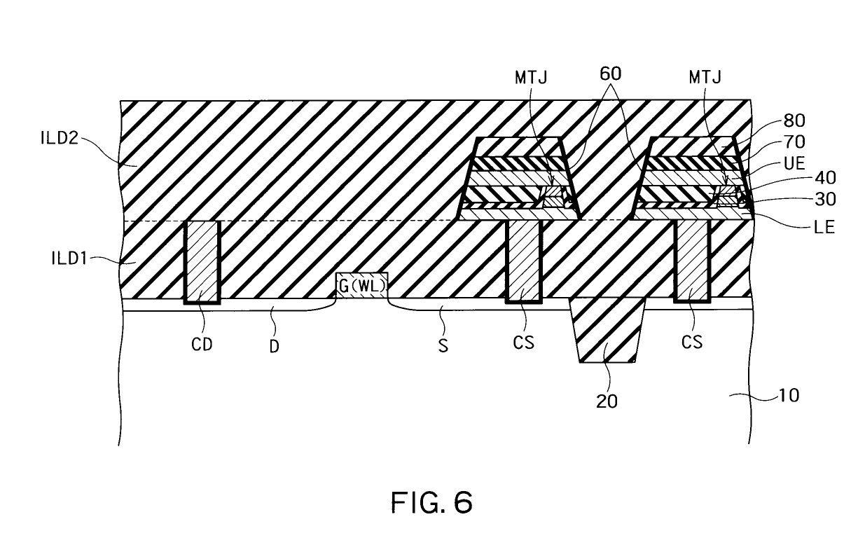

Thereafter, as shown in FIG. 6, the interlayer dielectric film ILD2 is deposited, and after flattening the interlayer dielectric film ILD2, the contact plug PLG1 is formed as shown in FIG. 1. Furthermore, the interlayer dielectric film ILD3 is deposited, and after flattening the interlayer dielectric film ILD3, the contact plug PLG2 is formed. By repeating the deposition of the interlayer dielectric film and the formation of the contact plug, a structure shown in FIG. 1 is obtained. Subsequently, a multilayer wiring structure (not shown) is formed, and hydrogen sinter annealing is performed. Although H radical is produced at this time, the first and second protection films 30 and 60 can suppress penetration of the H radical into the MTJ element. In this manner, the MRAM according to the present embodiment is completed.

The MRAM according to the present embodiment includes the second protection film 60 that covers the side surfaces of the upper electrode UE, the first protection film 30, and the insulation film 40 surrounding the MTJ element, as well as the first protection film 30 and the insulation film 40 that are provided directly on the side surface of the MTJ element. With this configuration, it is possible to suppress penetration of H radical, H₂O, O₂ and the like produced in a process of forming a multilayer wiring into the MTJ element and to suppress the degradation of the MTJ element. Therefore, in the present embodiment, it is possible to downscale the MTJ element to a sufficiently small size.

Further, when adopting tungsten in the contact plug and the multilayer wiring, there is a possibility that hydrogen is produced in a large amount in embedding the tungsten. However, even in this case, according to the present embodiment, the first and second protection films 30 and 60 can suppress penetration of the produced hydrogen into the MTJ element.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor memory device comprising:
a semiconductor substrate;
a select transistor on the semiconductor substrate;
a lower electrode electrically connected to one diffusion layer of the select transistor;
a magnetic tunnel junction element on the lower electrode;
a first protection film on a side surface of the magnetic tunnel junction element;
an upper electrode on the magnetic tunnel junction element and the first protection film; and
a second protection film on side surfaces of the upper electrode, the first protection film, and the lower electrode.

2. The device of claim 1, wherein the second protection film is made of a metal oxide film having an insulation characteristic.

3. The device of claim 1, wherein the second protection film is made of an oxide of a material of the lower electrode.

4. The device of claim 2, wherein the second protection film is made of an oxide of a material of the lower electrode.

5. The device of claim 1, wherein the second protection film is made of a material selected from TaOx, AlOx, IrOx, TiOx, WOx, or ZrOx, where x is a positive value.

6. The device of claim 2, wherein the second protection film is made of a material selected from TaOx, AlOx, IrOx, TiOx, WOx, or ZrOx, where x is a positive value.

7. The device of claim 3, wherein the second protection film is made of a material selected from TaOx, AlOx, IrOx, TiOx, WOx, or ZrOx, where x is a positive value.

8. The device of claim 1, wherein a thickness of the second protection film is equal to or less than 30 nm.

9. The device of claim 2, wherein a thickness of the second protection film is equal to or less than 30 nm.

10. The device of claim 3, wherein a thickness of the second protection film is equal to or less than 30 nm.

11. The device of claim 5, wherein a thickness of the second protection film is equal to or less than 30 nm.

12. The device of claim 1, wherein the first protection film is a laminated film which is formed by a first insulation film provided directly on a side surface of the magnetic tunnel junction element and a second insulation film provided on a side surface of the magnetic tunnel junction element via the first insulation film.

13. The device of claim 1, wherein the lower electrode is made by a material having conductivity, the material having an insulation characteristic when the material is oxidized.

14. A method of manufacturing a semiconductor memory device, comprising:
forming a transistor on a semiconductor substrate;
forming a contact plug connected to a diffusion layer of the transistor;
depositing a material of a lower electrode on the contact plug;
forming a magnetic tunnel junction element on a material of the lower electrode;
depositing a material of a first protection film on a top surface and a side surface of the magnetic tunnel junction element;
polishing a material of the first protection film until the top surface of the magnetic tunnel junction element is exposed;
depositing a material of an upper electrode on the magnetic tunnel junction element and the first protection film;
forming the upper electrode and the first protection film by processing a material of the upper electrode and a material of the first protection film;
attaching a material of the lower electrode to side surfaces of the upper electrode and the first protection film while removing the material of the lower electrode by using the upper electrode and the first protection film as a mask; and
forming a second protection film by oxidizing the material of the lower electrode attached on the side surfaces of the upper electrode and the first protection film.

15. The method of claim 14, wherein
the attachment of the material of the lower electrode is performed in an oxidizing atmosphere, and
the material of the lower electrode attached on the side surfaces of the upper electrode and the first protection film is oxidized simultaneously with the attachment of the material of the lower electrode.
